(19) United States
(12) Patent Application Publication
(10) Pub. No.: US 2025/0253293 A1
(43) Pub. Date: Aug. 7, 2025

(54) SEMICONDUCTOR PACKAGE AND METHOD OF FABRICATING THE SAME

(71) Applicant: SAMSUNG ELECTRONICS CO., LTD., Suwon-si (KR)

(72) Inventors: Dae Sung KIM, Suwon-si (KR); Kyung Hee LEE, Suwon-si (KR); Hyun Seok CHOI, Suwon-si (KR)

(73) Assignee: SAMSUNG ELECTRONICS CO., LTD., Suwon-si (KR)

(21) Appl. No.: 18/921,871

(22) Filed: Oct. 21, 2024

(30) Foreign Application Priority Data
Feb. 7, 2024 (KR) 10-2024-0018939

(51) Int. Cl. H01L 25/065; H01L 23/00; H01L 23/31; H01L 25/00; H10B 80/00

(52) U.S. Cl. CPC H01L 25/0657; H01L 23/3135; H01L 24/16; H01L 24/17; H01L 24/32; H01L 24/33; H01L 24/73; H01L 25/50; H01L 2224/16146; H01L 2224/17181; H01L 2224/32145; H01L 2224/33181; H01L 2224/73204; H01L 2224/73253; H01L 2225/06513; H01L 2225/06541; H01L 2225/06565; H10B 80/00

(57) ABSTRACT

A semiconductor package includes a base semiconductor chip, a first chip structure including first semiconductor chips that are vertically stacked on the base semiconductor chip, and a second chip structure disposed on the first chip structure and including second semiconductor chips that are vertically stacked on the first chip structure. Inactive surfaces of the first semiconductor chips are oriented in a first direction with respect to the base semiconductor chip, and active surfaces of the second semiconductor chips are oriented in the first direction with respect to the base semiconductor chip.

### CROSS-REFERENCE TO RELATED APPLICATION

This application claims priority from Korean Patent Application No. 10-2024-0018939 filed on Feb. 7, 2024 in the Korean Intellectual Property Office, the contents of which being herein incorporated by reference in its entirety.

### BACKGROUND

The present disclosure relates to a semiconductor package and a method of fabricating the same.

Due to developments in the electronics industry, there is an increasing demand for high functionality, high speed, and miniaturization of electronic components. Following this trend, high-density or high-integration packaging is emerging as an important factor.

For semiconductor packages that incorporate high-performance semiconductor chips, as technology advances, structures with multiple semiconductor chips that are stacked are being researched. However, the structures with multiple semiconductor chips that are stacked can experience bending deformation (or warpage) due to factors such as the coefficient of thermal expansion.

### SUMMARY

It is an aspect to provide a semiconductor package with improved reliability.

It is another aspect to provide a method of fabricating a semiconductor package with improved reliability.

According to an aspect of one or more embodiments, there is provided a semiconductor package comprising a base semiconductor chip; a first chip structure including a plurality of first semiconductor chips that are vertically stacked on the base semiconductor chip; and a second chip structure disposed on the first chip structure and including a plurality of second semiconductor chips that are vertically stacked on the first chip structure. Inactive surfaces of the plurality of first semiconductor chips are oriented in a first direction with respect to the base semiconductor chip, and active surfaces of the plurality of second semiconductor chips are oriented in the first direction with respect to the base semiconductor chip.

According to another aspect of one or more embodiments, there is provided a semiconductor package comprising a base semiconductor chip; a first chip structure including a plurality of first semiconductor chips that are vertically stacked on an upper surface of the base semiconductor chip; and a second chip structure disposed on the first chip structure and including a plurality of second semiconductor chips that are vertically stacked on the first chip structure. The plurality of first semiconductor chips include first front structures with first active surfaces and first back structures with first inactive surfaces, the plurality of second semiconductor chips include second front structures with second active surfaces and second back structures with second inactive surfaces, the first inactive surfaces are oriented in a first direction with respect to the base semiconductor chip, and the second inactive surfaces are oriented in the first direction with respect to the base semiconductor chip.

According to yet another aspect of one or more embodiments, there is provided a method of fabricating a semiconductor package, the method comprising providing a core semiconductor chip, which is disposed on a carrier substrate and includes a first surface, and a second surface that is opposite to the first surface and that is bonded to the carrier substrate; forming a second chip structure, which includes a plurality of second semiconductor chips that are vertically stacked to have active surfaces of the plurality of second semiconductor chips oriented toward the core semiconductor chip, on the first surface, the core semiconductor chip forming a lowermost second semiconductor chip; flipping the carrier substrate such that the second surface is above the first surface, and detaching the carrier substrate; forming a first chip structure, which includes a plurality of first semiconductor chips that are vertically stacked to have active surfaces of the plurality of first semiconductor chips oriented toward the second surface, on the second surface of the core semiconductor chip, to form a first die including the first chip structure and the second chip structure; and flipping the first die such that the first chip structure and the second chip structure are sequentially stacked, and attaching the first die that has been flipped on a base semiconductor chip.

### BRIEF DESCRIPTION OF THE DRAWINGS

The above and other aspects will become more apparent by describing in detail example embodiments thereof with reference to the attached drawings, in which:

FIG. 1 is a drawing for explaining a semiconductor package according to some embodiments;

FIGS. 2 through 12 are cross-sectional diagrams for explaining a method of fabricating a semiconductor package according to some embodiments;

FIG. 13 is a cross-sectional view for explaining a semiconductor package according to some embodiments;

FIG. 14 is a cross-sectional view for explaining a semiconductor package according to some embodiments;

FIGS. 15 and 16 are cross-sectional views for explaining semiconductor packages according to some embodiments; and

FIG. 17 is a cross-sectional view for explaining a semiconductor package according to some embodiments.

### DETAILED DESCRIPTION

In this specification, although terms such as “first,” “second,” “upper,” and “lower” are used to describe various elements or components, these elements or components are not limited by these terms. These terms are merely used to distinguish one element or component from another. Therefore, a “first” element or component mentioned below may be a “second” element or component (or vice versa) within the technical spirit of the present disclosure. Similarly, a “lower” element or component mentioned below may be an “upper” element or component (or vice versa) within the technical spirit of the present disclosure. Moreover, as used in this specification, the phrase “at least one of A, B, or C” includes within its scope “only A”, “only B”, “only C”, “A and B”, “A and C”, “B and C”, and “A, B, and C.”

Embodiments of the present disclosure will hereinafter be described in detail with reference to the attached drawings. The same reference numerals are used for the same elements in the drawings, and redundant descriptions thereof will be omitted for conciseness.

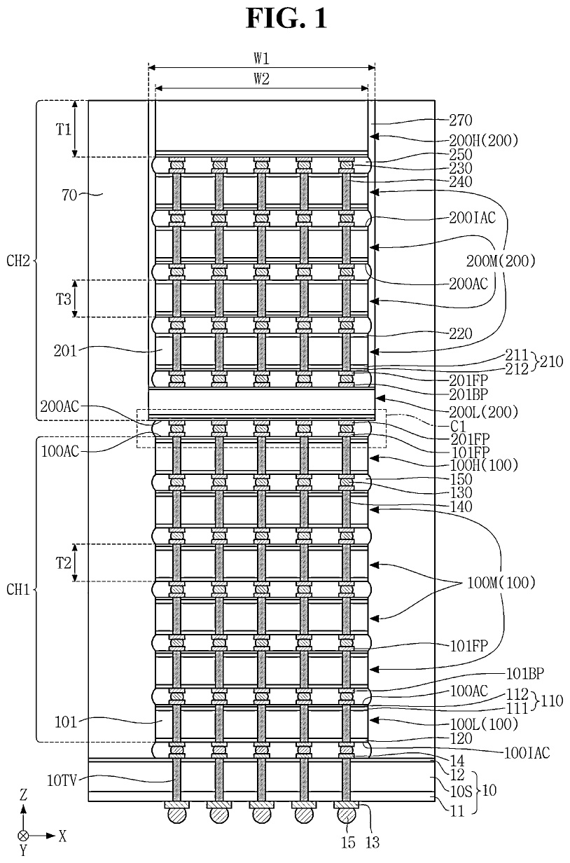

FIG. 1 is a drawing for explaining a semiconductor package according to some embodiments.

A semiconductor package according to some embodiments will hereinafter be described with reference to FIG. 1.

Referring to FIG. 1, the semiconductor package may include a base semiconductor chip 10, a first chip structure CH1, a second chip structure CH2, and a mold layer 70.

In an embodiment, the base semiconductor chip 10 may include a semiconductor material such as silicon (Si). The base semiconductor chip 10 may extend in a first direction X. In this specification, the first direction X, a second direction Y, and a third direction Z may intersect one another. The first direction X, the second direction Y, and the third direction Z may be substantially perpendicular to one another.

The base semiconductor chip 10 may include a base substrate 10S, a base front structure 11, a base back structure 12, base front pads 13, base back pads 14, base through vias 10TV, and external connection terminals 15.

In an embodiment, the base semiconductor chip 10 may be, for example, a buffer chip that includes a plurality of logic elements and/or memory elements disposed on the base front structure 11. Therefore, the base semiconductor chip 10 may transmit signals from a plurality of semiconductor chips (e.g., semiconductor chips 100 and 200 described below), which are stacked on the base semiconductor chip 10, to the outside through the external connection terminals 15 and may transmit signals and power from the outside to the semiconductor chips (100 and 200). The base semiconductor chip 10 may perform both logic and memory functions through the logic elements and memory elements, but embodiments are not limited thereto. In some embodiments, the base semiconductor chip 10 may include only the logic elements and may perform only logic functions. In some embodiments, the base semiconductor chip 10 may be a printed circuit board (PCB), a ceramic substrate, or an interposer.

The base substrate 10S may refer to the area between the base front structure 11 and the base back structure 12. The base substrate 10S may have a larger length than first substrates 101 and second substrates 201 in the first direction X.

In some embodiments, the base substrate 10S may include, for example, a semiconductor element such as Si or germanium (Ge), or a compound semiconductor such as silicon carbide (SiC), gallium arsenide (GaAS), indium arsenide (InAs), or indium phosphide (InP). In some embodiments, the base substrate 10S may have a silicon-on-insulator (SOI) structure. In some embodiments, the base substrate 10S may include conductive areas, for example, wells doped with impurities, or structures doped with impurities. In some embodiments, the base substrate 10S may include various component separation structures, such as a shallow trench isolation (STI) structure.

The base front structure 11 may be disposed on the bottom surface of the base substrate 10S. The base front structure 11 may include various types of components. For example, in some embodiments, the base front structure 11 may include field-effect transistors (FETs) such as a planar FET or FinFET, memories such as a flash memory, dynamic random-access memory (DRAM), static random-access memory (SRAM), electrically erasable programmable read-only memory (EEPROM), phase-change random access memory (PRAM), magnetoresistive random-access memory (MRAM), ferroelectric random-access memory (FeRAM), and/or resistive random-access memory (RRAM), logic components such as an AND, OR, NOT element, and/or various active and/or passive components such as system Large Scale Integration (LSI), CMOS Imaging Sensor (CIS), and/or Micro-Electro-Mechanical System (MEMS).

In some embodiments, the base front structure 11 may include interlayer insulating layers and multilayer wiring layers that are electrically connected to these components. The wiring layers may electrically connect the components to one another, to the conductive areas on the base substrate 10S, or to the external connection terminals 15. In some embodiments, the base front structure 11 may be protected by a separate passivation layer that includes at least one of silicon oxide, silicon nitride, and silicon oxynitride.

The base back structure 12 may be disposed on the upper surface of the base substrate 10S. The base back structure 12 may face the first chip structure CH1. The base back structure 12 may include a passivation layer that protects the base substrate 10S.

The base front pads 13 may be disposed on the base front structure 11. In some embodiments, the base front pads 13 may include, for example, at least one of aluminum (Al), copper (Cu), nickel (Ni), tungsten (W), platinum (Pt), or gold (Au).

The external connection terminals 15 may be disposed on the base front pads 13. The external connection terminals 15 may be electrically connected to the external connection terminals 15. The external connection terminals 15 may protrude from the base front pads 13 in the third direction Z.

In some embodiments, the external connection terminals 15 may be solder bumps that include a low-melting-point metal, for example, tin (Sn) and/or a tin alloy, but embodiments are not limited thereto. In some embodiments, the external connection terminals 15 may various shapes such as lands, balls, pins, and pillars. The external connection terminals 15 may be formed as single layers or multilayers. When formed as single layers, the external connection terminals 15 may include, for example, tin-silver (Sn—Ag) solder or copper (Cu). When formed as multilayers, the external connection terminals 15 may include, for example, Cu filler and solder. The number, spacing, and arrangement of the external connection terminals 15 are not limited to what is illustrated in FIG. 1 and may vary according to the semiconductor package according to some embodiments. In some embodiments, the external connection terminals 15 may include, for example, at least one of Sn, indium (In), lead (Pb), zinc (Zn), Ni, Au, silver (Ag), Cu, antimony (Sb), or bismuth (Bi), or a combination thereof, but embodiments are not limited thereto.

In some embodiments, the external connection terminals 15 may be parts of the semiconductor package according to some embodiments that are electrically connected to an external device, for example, the panel of an electronic device. For example, the semiconductor package according to some embodiments may be mounted on an external substrate such as a mainboard via the external connection terminals 15.

The base back pads 14 may be disposed on the base back structure 12. The description of the base back pads 14 may be substantially the same as the description above of the base front pads 13.

The base through vias 10TV may penetrate the base substrate 10S in the third direction Z. The base through vias 10TV may be electrical paths that connect the base front pads 13 and the base back pads 14. In an embodiment, the base through vias 10TV may include a conductive plug and a barrier film surrounding the conductive plug. The conductive plug may include, for example, a metal material such as W, Ti, Al, and/or Cu. The conductive plug may be formed by plating, physical vapor deposition (PVD), or chemical vapor deposition (CVD). The barrier film may include an insulating barrier film and/or a conductive barrier film. The insulating barrier film may be formed of an oxide film, nitride film, carbide film, polymer, or a combination thereof. For example, the conductive barrier film may be disposed between the insulating barrier film and the conductive plug. The conductive barrier film may include a metal compound such as tungsten nitride (WN), titanium nitride (TiN), and/or tantalum nitride (TaN). The barrier film may be formed by PVD and/or CVD.

The first chip structure CH1 may be disposed on the base semiconductor chip 10. The first chip structure CH1 may be disposed on the base back structure 12 of the base semiconductor chip 10.

The first chip structure CH1 may include a plurality of first semiconductor chips 100 that are vertically stacked, first front pads 101FP, first back pads 101BP, first bumps 130, first through vias 140, and a first underfill 150. In the first chip structure CH1, the first semiconductor chips 100, first front pads 101FP, first bumps 130, and first back pads 101BP may be stacked in repeating order.

The first semiconductor chips 100 may be vertically stacked in the third direction Z. The first semiconductor chips 100 may include a lowermost first semiconductor chip 100L, middle first semiconductor chips 100M, and an uppermost first semiconductor chip 100H. The middle first semiconductor chips 100M may be disposed between the uppermost first semiconductor chip 100H and the lowermost first semiconductor chip 100L. The semiconductor package of FIG. 1 is illustrated as including four middle first semiconductor chips 100M, but embodiments are not limited thereto.

The lowermost first semiconductor chip 100L may be disposed closest to the base semiconductor chip 10 among the first semiconductor chips 100. The middle first semiconductor chips 100M may be disposed on the lowermost first semiconductor chip 100L. The uppermost first semiconductor chip 100H may be disposed on an uppermost one of the middle first semiconductor chips 100M.

In an embodiment, the widths, in the first direction X, of the first semiconductor chips 100 may all be the same, but embodiments are not limited thereto. For example, in an embodiment, the widths, in the first direction X, of the lowermost first semiconductor chip 100L, the middle first semiconductor chips 100M, and the uppermost first semiconductor chip 100H may all be the same. In some embodiments, the widths, in the first direction X, of the lowermost first semiconductor chip 100L, the middle first semiconductor chips 100M, and the uppermost first semiconductor chip 100H may differ from one another.

In an embodiment, the first semiconductor chips 100 may all have the same thickness (i.e., a second thickness T2) in the third direction Z, but embodiments are not limited thereto. For example, in an embodiment, the thicknesses, in the third direction Z, of the lowermost first semiconductor chip 100L, the middle first semiconductor chips 100M, and the uppermost first semiconductor chip 100H may all be the same. In some embodiments, the thicknesses, in the third direction Z, of the lowermost first semiconductor chip 100L, the first middle semiconductor chips 100M, and the uppermost first semiconductor chip 100H may differ from one another.

The first semiconductor chips 100 may include the first substrates 101, first front structures 110, and first back structures 120.

The first substrates 101 may refer to the areas between the first front structures 110 and the first back structures 120 as illustrated in FIG. 1. For example, the first substrates 101 may include a semiconductor element such as Si and/or Ge, but embodiments are not limited thereto. The description of the first substrates 101 may be substantially the same as for the description of the base substrate 10S.

The first front structures 110 may be disposed on the upper surfaces of the first substrates 101. The first front structures 110 may include first active surfaces 100AC. In the first chip structure CH1, the first active surfaces 100AC of the first semiconductor chips 100 may not be oriented toward the base semiconductor chip 10. For example, if the upper surface of the base semiconductor chip 10 is oriented in the positive direction of the third direction Z, the first active surfaces 100AC may also be oriented in the positive direction of the third direction Z.

The first front structures 110 may include first device layers 111 and first passivation layers 112.

The first device layers 111 may include multiple memory devices. For example, the first device layers 111 may include non-volatile memory devices such as DRAMs or SRAMs or inactive memory devices such as PRAMs, MRAMs, FeRAMs, or RRAMs. For example, DRAM devices may be disposed in the first device layers 111 of the first semiconductor chips 100. Consequently, in some embodiments, the semiconductor package according to some embodiments may be utilized in a High Bandwidth Memory (HBM) or Electro Data Processing (EDP) product.

The first device layers 111 may include interlayer insulating films and multilayer wiring layers that are electrically connected to the memory devices within the first device layers 111. The memory devices in the first device layers 111 may be electrically connected to the first bumps 130 through the multilayer wiring layers.

The first passivation layers 112 may be disposed on the first device layers 111. The first passivation layers 112 may include at least one of silicon oxide, silicon nitride, or silicon oxynitride.

The first back structures 120 may be disposed on the bottom surfaces of the first substrates 101. The first back structures 120 may include first inactive surfaces 100IAC. The first inactive surfaces 100IAC may be oriented toward the base semiconductor chip 10. Specifically, the first inactive surfaces 100IAC may be oriented toward the upper surface of the base semiconductor chip 10. For example, if the upper surface of the base semiconductor chip 10 is oriented in the positive direction of the third direction Z, the first inactive surfaces 100IAC may be oriented in the negative direction of the third direction Z.

The first back structures 120 may include passivation layers that protect the first substrates 101.

The first front pads 101FP may be disposed on the first front structures 110. The first front pads 101FP may be disposed on the first active surfaces 100AC. The first front pads 101FP may be exposed from the first active surfaces 100AC. The first front pads 101FP may not face the base semiconductor chip 10.

The first back pads 101BP may be disposed on the first back structures 120. The first back pads 101BP may be disposed on the first inactive surfaces 100IAC. The first back pads 101BP may be exposed from the first inactive surfaces 100IAC. The first back pads 101BP may face the base semiconductor chip 10.

The first front pads 101FP and the first back pads 101BP may include, for example, a metal material such as Al, Cu, Ni, W, Pt, and/or Au, but embodiments are not limited thereto.

The first front pads 101FP and the first back pads 101BP are illustrated in FIG. 1 as having a rectangular shape, but embodiments are not limited thereto. In some embodiments, the first front pads 101FP and the first back pads 101BP may have various shapes such as circular plates, elliptical plates, or polygonal plates.

The first bumps 130 may be disposed between the first front pads 101FP and the first back pads 101BP. The first front pads 101FP may be electrically connected to the first back pads 101BP by the first bumps 130.

In an embodiment, the first bumps 130 may be solder bumps containing a low-melting-point metal, such as Sn and/or a Sn alloy, but embodiments are not limited thereto. In some embodiments, the first bumps 130 may have various shapes such as lands, balls, pins, and pillars. In an embodiment, the first bumps 130 may include Under Bump Metallurgy (UBM).

The first bumps 130 may be formed as single layers or multilayers. When formed as single layers, the first bumps 130 may include, for example, Sn—Ag solder or Cu. When formed as multilayers, the first bumps 130 may include Cu filler and solder. The number, spacing, and arrangement of the first bumps 130 are not limited to what is illustrated in FIG. 1 and may vary according to the semiconductor package according to some embodiments.

The first through vias 140 may be disposed to penetrate the first semiconductor chips 100. The first through vias 140 may be connected to the first front pads 101FP and the first back pads 101BP. The first front pads 101FP and the first back pads 101BP may be electrically connected by the first through vias 140. The description of the first through vias 140 may be similar to the description of the base through vias 10TV.

The first underfill 150 may be disposed between the base semiconductor chip 10 and the lowermost first semiconductor chip 100L, and between each pair of adjacent first semiconductor chips 100. The first underfill 150 may also be disposed in a first area C1 between the first chip structure CH1 and the second chip structure CH2.

The first underfill 150 may fill the space between the base semiconductor chip 10 and the lowermost first semiconductor chip 100L. The first underfill 150 may fill the space between each pair of adjacent first semiconductor chips 100. The first underfill 150 may cover the first front pads 101FP, the first back pads 101BP, and the first bumps 130.

In an embodiment, the first underfill 150 may protrude in the first direction X beyond the sides of the first semiconductor chips 100. In an embodiment, the first underfill 150 may be a non-conductive film (NCF), but embodiments are not limited thereto. For example, in some embodiments, the first underfill 150 may include any type of polymer film suitable for a thermocompression bonding process.

The second chip structure CH2 may be disposed on the first chip structure CH1. The second chip structure CH2 may be disposed on the uppermost first semiconductor chip 100H of the first chip structure CH1.

The second chip structure CH2 may include a plurality of second semiconductor chips 200 that are vertically stacked, second front pads 201FP, second back pads 201BP, second bumps 230, second through vias 240, a second underfill 250, and a liner film 270. In the second chip structure CH2, the second semiconductor chips 200, second back pads 201BP, second bumps 230, and second front pads 201FP may be stacked in repeating order.

The second semiconductor chips 200 may be stacked in the third direction Z. The second semiconductor chips 200 may include a lowermost second semiconductor chip 200L, middle second semiconductor chips 200M, and an uppermost second semiconductor chip 200H. The middle second semiconductor chips 200M may be disposed between the uppermost second semiconductor chip 200H and the lowermost second semiconductor chip 200L. The semiconductor package of FIG. 1 is illustrated as including four middle second semiconductor chips 200M, but embodiments are not limited thereto.

The lowermost second semiconductor chip 200L may be disposed closest to the first chip structure CH1 among the second semiconductor chips 200. For example, in an embodiment, the lowermost second semiconductor chip 200L may be disposed directly on the uppermost first semiconductor chip 100H. The area where the lowermost second semiconductor chip 200L and the uppermost first semiconductor chip 100H are connected may be the first area C1 where the first and second chip structures CH1 and CH2 are connected.

In the first area C1, the uppermost first semiconductor chip 100H and the lowermost second semiconductor chip 200L may face each other. For example, the front structure 110 of the uppermost first semiconductor chip 100H may face a front structure 210 of the lowermost second semiconductor chip 200L. In other words, the first active surface 100AC of the uppermost first semiconductor chip 100H may face a second active surface 200AC of the lowermost second semiconductor chip 200L.

In the first area C1, the first front pads 101FP on the front structure 110 of the uppermost first semiconductor chip 100H and the second front pads 201FP on the front structure 210 of the lowermost second semiconductor chip 200L may be connected through the first bumps 130. In the first area C1, the first front pads 101FP, the second front pads 201FP, and the first bumps 130 may be covered by the first underfill 150.

The first front pads 101FP, the first bumps 130, and the second front pads 201FP may be sequentially arranged in the first area C1.

The first and second chip structures CH1 and CH2 may be asymmetric with respect to the first area C1.

In an embodiment, the lowermost second semiconductor chip 200L may have a different width from the other second semiconductor chips 200 in the first direction X. For example, in an embodiment, a width W1, in the first direction X, of the lowermost second semiconductor chip 200L may be larger than a width W2, in the first direction X, of the middle second semiconductor chips 200M and the uppermost second semiconductor chip 200H.

In an embodiment, the lowermost second semiconductor chips 200L may protrude beyond the sides of the middle second semiconductor chips 200M in the first direction X. In an embodiment, the lowermost second semiconductor chip 200L may protrude beyond the sides of the uppermost second semiconductor chip 200H in the first direction X.

The uppermost second semiconductor chip 200H may be disposed on an uppermost one of the middle second semiconductor chips 200M. The uppermost second semiconductor chip 200H, unlike the lowermost second semiconductor chip 200L and the middle second semiconductor chips 200M, may not include a second back structure 220.

A first thickness T1, in the third direction Z, of the uppermost second semiconductor chip 200H may be greater than a second thickness T2, in the third direction Z, of the first semiconductor chips 100 and a third thickness T3, in the third direction Z, of the other second semiconductor chips 200.

The second semiconductor chips 200 may include the second substrates 201, the second front structures 210, and the second back structures 220.

The second substrates 201 may refer to the areas between the second front structures 210 and the second back structures 220. The description of the second substrates 201 may be substantially the same as the description of the first substrates 101.

The second front structures 210 may be disposed on the bottom surfaces of the second substrates 201. The second front structures 210 may include second active surfaces 200AC. In the second chip structure CH2, the second active surfaces 200AC of the second semiconductor chips 200 may be oriented toward the base semiconductor chip 10. Specifically, the second active surfaces 200AC may be oriented toward the upper surface of the base semiconductor chip 10. For example, if the upper surface of the base semiconductor chip 10 is oriented in the positive direction of the third direction Z, the second active surfaces 200AC may be oriented in the negative direction of the third direction Z.

The second front structures 210 may include second device layers 211 and second passivation layers 212. The descriptions of the second device layers 211 and the second passivation layers 212 may be substantially the same as the descriptions, respectively, of the first device layers 111 and the first passivation layers 112 in the first chip structure CH1.

The second back structures 220 may be disposed on the upper surfaces of the second substrates 201. The second back structures 220 may include second inactive surfaces 200IAC. The second inactive surfaces 200IAC may not be oriented toward the base semiconductor chip 10. Specifically, the second inactive surfaces 200IAC may not face the upper surface of the base semiconductor chip 10. For example, if the upper surface of the base semiconductor chip 10 is oriented in the positive direction of the third direction Z, the second inactive surfaces 200IAC may be oriented in the positive direction of the third direction Z.

The second back structure 220 may not be disposed on the upper surface of the uppermost second semiconductor chip 200H.

The second back structures 220 may include passivation layers that protect the second substrates 201.

The second front pads 201FP may be disposed on the second front structures 210. The second front pads 201FP may be disposed on the second active surfaces 200AC. The second front pads 201FP may be exposed from the second active surfaces 200AC. The second front pads 201FP may be oriented toward the base semiconductor chip 10. That is, the second front pads 201FP may be oriented in the negative direction of the third direction Z.

The second back pads 201BP may be disposed on the second back structure 220. The second back pads 201BP may be disposed on the second inactive surfaces 200IAC. The second back pads 201BP may be exposed from the second inactive surfaces 200IAC. The second back pads 201BP may not be oriented toward the base semiconductor chip 10. That is, the second back pads 201BP may be oriented in the positive direction of the third direction Z.

In some embodiments, the second front pads 201FP and the second back pads 201BP may include a metal such as Al, Cu, Ni, W, Pt, and/or Au, but embodiments are not limited thereto.

The second front pads 201FP and the second back pads 201BP are illustrated in FIG. 1 as having a rectangular shape, but embodiments are not limited thereto. In some embodiments, the second front pads 201FP and the second back pads 201BP may have a circular, elliptical, or polygonal plate shape.

The second bumps 230 may be disposed between the second front pads 201FP and the second back pads 201BP. The second front pads 201FP may be electrically connected to the second back pads 201BP by the second bumps 230. The description of the second bumps 230 may be substantially similar to the description of the first bumps 130.

The second through vias 240 may be disposed to penetrate the second semiconductor chips 200, except for the uppermost second semiconductor chip 200H. For example, the second through vias 240 may be disposed to penetrate the lowermost first semiconductor chip 100L and the middle second semiconductor chips 200M, but may not be disposed within the uppermost second semiconductor chip 200H.

The second through vias 240 may be connected to the second front pads 201FP and the second back pads 201BP. The second through vias 240 may be electrically connected to the second front pads 201FP and the second back pads 201BP. The description of the second through vias 240 may be similar to the description of the base through vias 10TV.

The second underfill 250 may be disposed between each pair of adjacent second semiconductor chips 200. For example, the second underfill 250 may be disposed between the lowermost second semiconductor chip 200L and the middle second semiconductor chips 200M. The second underfill 250 may also be disposed between the middle second semiconductor chips 200M. The second underfill 250 may also be disposed between the middle second semiconductor chips 200M and the uppermost second semiconductor chip 200H.

The second underfill 250 may cover the second front pads 201FP, the second back pads 201BP, and the second bumps 230, between each pair of adjacent second semiconductor chips 200.

In an embodiment, the second underfill 250 may protrude beyond the sides of the middle second semiconductor chips 200M and the uppermost second semiconductor chip 200H in the first direction X, but may not protrude beyond the sides of the lowermost second semiconductor chip 200L in the first direction X. In other words, the sides of the lowermost second semiconductor chip 200L may protrude beyond the second underfill 250 in the first direction X.

The description of the second underfill 250 may be substantially the same as the description of the first underfill 150.

The liner film 270 may be disposed between the mold layer 70 and the second semiconductor chips 200. The liner film 270 may be disposed between the second underfill 250 and the mold layer 70.

The liner film 270 may cover the sides of the second underfill 250. The liner film 270 may cover the sides of the uppermost second semiconductor chip 200H and the sides of the middle second semiconductor chips 200M. The liner film 270 may not cover the sides of the lowermost second semiconductor chip 200L. The upper surface of the uppermost second semiconductor chip 200H may not be covered by the liner film 270.

The liner film 270 may expose the sides of the lowermost second semiconductor chip 200L. The sides of the liner film 270 may be aligned in a same plane as the sides of the lowermost second semiconductor chip 200L. In other words, in some embodiments, the sides of the liner film 270 may be coplanar with the sides of the lowermost second semiconductor chip 200L.

The liner film 270 may contact part of the upper surface of the lowermost second semiconductor chip 200L. The liner film 270 may be disposed on the upper surface of the lowermost second semiconductor chip 200L. The liner film 270 may be disposed on the second back structure 220 of the lowermost second semiconductor chip 200L. That is, the liner film 270 may be disposed on the second inactive surface 200IAC of the lowermost second semiconductor chip 200L.

In some embodiments, the liner film 270 may include, for example, an epoxy-based resin, benzocyclobutene (BCB), and/or polyimide, but embodiments are not limited thereto. In an embodiment, the liner film 270 may include, for example, an insulating polymer material such as Epoxy Molding Compound (EMC). In an embodiment, the liner film 270 may include the same material as the second underfill 250, but embodiments are not limited thereto. In some embodiments, the liner film 270 may include a different material from the second underfill 250.

The mold layer 70 may be disposed on the base semiconductor chip 10. The mold layer 70 may cover part of the upper surface of the base semiconductor chip 10 and the first and second chip structures CH1 and CH2. Specifically, the mold layer 70 may cover the sides of the first semiconductor chips 100 and the sides of the first underfill 150. The mold layer 70 may cover the sides of the lowermost second semiconductor chip 200L and the liner film 270. The mold layer 70 may not directly touch the sides of the middle second semiconductor chips 200M and the sides of the uppermost second semiconductor chip 200H due to the liner film 270. The mold layer 70 may not cover the upper surface of the uppermost second semiconductor chip 200H. That is, the mold layer 70 may expose the upper surface of the uppermost second semiconductor chip 200H.

In an embodiment, the mold layer 70 may include a material such as an epoxy-based resin, BCB, or polyimide, but embodiments are not limited thereto. In an embodiment, the liner film 270 may include, for example, an insulating polymer material such as EMC, but embodiments are not limited thereto. In some embodiments, the mold layer 70 may include the same material as the first underfill 150, the second underfill 250, and the liner film 270, but embodiments are not limited thereto. In some embodiments, the mold layer 70, the first underfill 150, the second underfill 250, and the liner film 270 may include different materials from one another.

With the advancement in the electronics industry, there is an increasing demand for semiconductor package technologies that feature high-performance semiconductor chips. As technology progresses, three-dimensional (3D) stack packages, which employ the vertical stacking of multiple semiconductor chips, are being introduced. However, the vertical stacking of multiple semiconductor chips introduces challenges such as the increased use of non-conductive films (NCFs) between semiconductor chips and the variances in the coefficient of thermal expansion among components. These factors can lead to warpage as the height of semiconductor chip stacks increases. Warpage, in turn, can cause delamination between components and cracks in substrates, compromising the reliability of semiconductor devices.

On the contrary, the semiconductor package according to some embodiments may include the base semiconductor chip 10, the first chip structure CH1, and the second chip structure CH2. The base semiconductor chip 10, the first chip structure CH1, and the second chip structure CH2 may be sequentially stacked vertically. The first chip structure CH1 may have a plurality of first semiconductor chips 100 stacked vertically. The second chip structure CH2 may have a plurality of second semiconductor chips 200 stacked vertically. The first semiconductor chips 100 may include the first front structures 110 with the first active surfaces 100AC and first back structures 120 with the first inactive surfaces 100IAC. The second semiconductor chips 200 may include the second front structures 210 with the second active surfaces 200AC and the second back structures 220 with the second inactive surfaces 200IAC. In the first chip structure CH1, the first active surfaces 100AC may be oriented toward the second chip structure CH2, and the first inactive surfaces 100IAC may be oriented toward the base semiconductor chip 10. In the second chip structure CH2, the second active surfaces 200AC may be oriented toward the base semiconductor chip 10, and the second inactive surfaces 200IAC may be oriented in the positive direction of the third direction Z.

Each semiconductor chip may include active and inactive surfaces. In a related art vertical stacking semiconductor package, a plurality of semiconductor chips are arranged such that their active surfaces all face the same direction. However, in the semiconductor package according to some embodiments, semiconductor chips may be stacked in the first chip structure CH1 to have their active surfaces face toward the positive direction of the third direction Z, and semiconductor chips may be stacked in the second chip structure CH2 to have their active surfaces face toward the negative direction of the third direction Z. In this manner, the direction of stress or force on the semiconductor chips can be dispersed, preventing warpage. Thus, a semiconductor package with improved reliability can be provided.

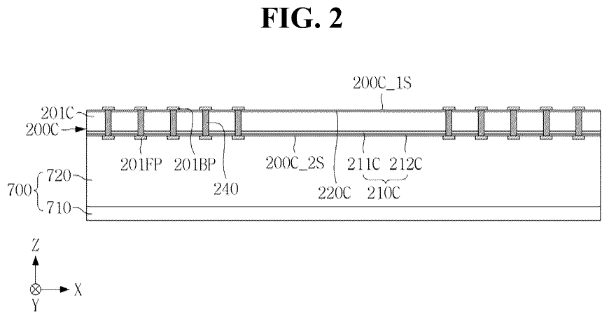

FIGS. 2 through 12 are cross-sectional diagrams for explaining a method of fabricating a semiconductor package according to some embodiments. For convenience, descriptions of elements that have been described above with reference to FIG. 1 will be simplified or omitted for conciseness.

Referring to FIG. 2, a core semiconductor chip 200C, which is disposed on a first carrier substrate 700, may be provided.

The first carrier substrate 700 may extend in the first direction X. The first carrier substrate 700 may include a first support substrate 710 and a first glue layer 720.

The first support substrate 710 may include any suitable material, such as stainless steel, glass, or a silicon fiberglass reinforced epoxy. The first glue layer 720 may be disposed on the first support substrate 710. The first glue layer 720 may be a suitable adhesive that can facilitate bonding during the fabrication of the semiconductor package according to some embodiments, and may be removed at the end of the fabrication of the semiconductor package according to some embodiments.

The core semiconductor chip 200C may include a first surface 200C_1S and a second surface 200C_2S, which is opposite to the first surface 200C_1S and is bonded to the first carrier substrate 700. The first surface 200C_1S may be an inactive surface. The second surface 200C_2S may be an active surface.

The core semiconductor chip 200C may include a core substrate 201C, a core front structure 210C, a core back structure 220C, second front pads 201FP, second back pads 201BP, and second through vias 240. The core semiconductor chip 200C may become a lowermost second semiconductor chip 200L in a final product.

The core substrate 201C may be disposed between the core front structure 210C and the core back structure 220C. The description of the core substrate 201C may be substantially the same as the description of the second substrate 201.

The core front structure 210C may be disposed near the second surface 200C_2S. The core front structure 210C may include a core device layer 211C and a core passivation layer 212C. The description of the core front structure 210C may be substantially the same as the description of the second front structure 210.

The core back structure 220C may be disposed near the first surface 200C_1S. The description of the core back structure 220C may be substantially the same as the description of the second back structure 220.

The second front pads 201FP may be disposed on the core front structure 210C. The second front pads 201FP may be disposed on the second surface 200C_2S. The second front pads 201FP may be disposed on the active surface of the core semiconductor chip 200C.

The second back pads 201BP may be disposed on the core back structure 220C. The second back pads 201BP may be disposed on the first surface 200C_1S. The second back pads 201BP may be disposed on the inactive surface of the core semiconductor chip 200C.

The second through vias 240 may penetrate the core semiconductor chip 200C. The second through vias 240 may be connected to the second front pads 201FP and the second back pads 201BP. The second through vias 240 may electrically connect the second front pads 201FP and the second back pads 201BP.

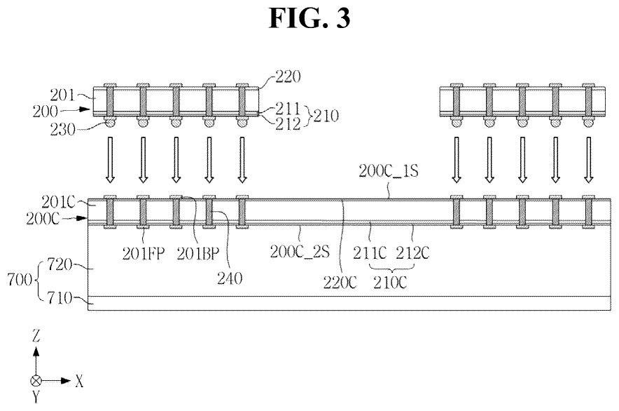

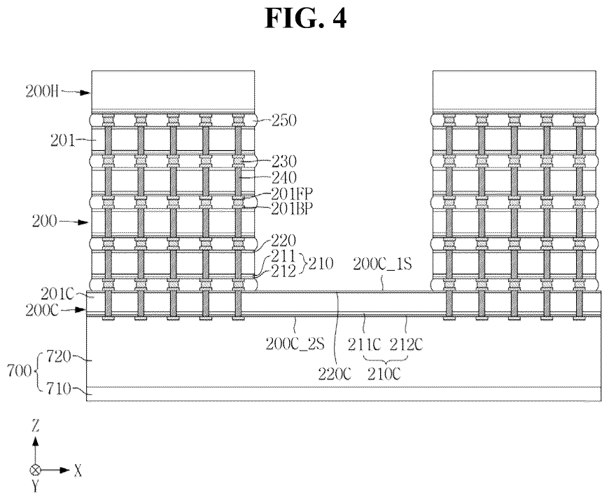

Referring to FIGS. 3 and 4, a plurality of second semiconductor chips 200 may be vertically stacked on the first surface 200C_1S of the core semiconductor chip 200C.

Each of the second semiconductor chips 200 may include a second substrate 201, a second front structure 210, a second back structure 220, second front pads 201FP, second back pads 201BP, second bumps 230, and second through vias 240.

Specifically, referring to FIG. 3, when second semiconductor chips 200 near the core semiconductor chip 200C are disposed on the first surface 200C_1S of the core chip 200C, the second front structures 210 of the second semiconductor chips 200 may be disposed to be oriented toward the first surface 200C_1S of the core semiconductor chip 200C. Thus, the active surfaces of the second semiconductor chips 200 may be oriented toward the first surface 200C_1S of the core semiconductor chip 200C. The second semiconductor chips 200 may be disposed when the second bumps 230 are attached to the second back pads 201BP of the core semiconductor chip 200C. In an embodiment, a second semiconductor chip 200 may be disposed on a left hand side of the core semiconductor chip 200C, and a second semiconductor chip 200 may be disposed on a right hand side of the core semiconductor chip 200C to be spaced apart in the first direction X from the second semiconductor chip 200 that is disposed on the left hand side, as illustrated in FIG. 3.

Thereafter, referring to FIG. 4, subsequent second semiconductor chips 200 may be vertically stacked on the first surface 200C_1S of the core semiconductor chip 200C. The second front structures 210 of the subsequent second semiconductor chips 200 may be oriented toward the core semiconductor chip 200C. That is, the active surfaces of the subsequent second semiconductor chips 200 may be oriented toward the first surface 200C_1S of the core semiconductor chip 200C. Specifically, the second semiconductor chips 200 may be stacked such that their active surfaces may be oriented toward the first surface 200C_1S of the core semiconductor chip 200C. In an embodiment, a plurality of subsequent second semiconductor chips 200 may be disposed on the left hand side of the core semiconductor chip 200C, and a plurality of subsequent second semiconductor chips 200 may be disposed on the right hand side of the core semiconductor chip 200C to be spaced apart in the first direction X from the subsequent second semiconductor chips 200 that are disposed on the left hand side, as illustrated in FIG. 4.

Uppermost second semiconductor chips 200H among the second semiconductor chips 200 may not include second back structures 220. The thickness, in the third direction Z, of the uppermost second semiconductor chips 200H may be greater than the thickness, in the third direction Z, of the other second semiconductor chips 200.

A second underfill 250 may be disposed between the core semiconductor chip 200C and the second semiconductor chips 200, and between each pair of vertically adjacent second semiconductor chips 200. The second underfill 250 may surround the second bumps 230 between the core semiconductor chip 200C and the second semiconductor chips 200, and between each pair of vertically adjacent second semiconductor chips 200. The second underfill 250 may protrude beyond the sides of the second semiconductor chips 200 in the first direction X.

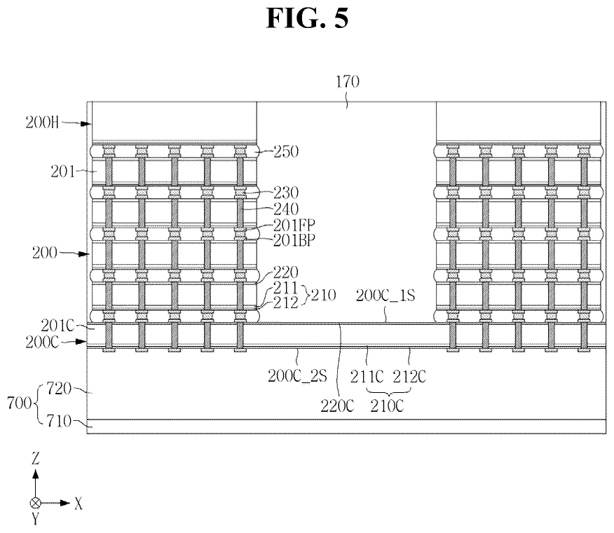

Referring to FIG. 5, a pre-liner film 170 may be formed on the core semiconductor chip 200C.

The pre-liner film 170 may surround the second semiconductor chips 200 on the core semiconductor chip 200. The pre-liner film 170 may cover the sides of the second semiconductor chips 200. The pre-liner film 170 may cover the sides of the second underfill 250. The pre-liner film 170 may become a liner film 270 in the final structure. The pre-liner film 170 may fill the space between each pair of second semiconductor chips 200 that are spaced apart in the first direction X.

The pre-liner film 170 may expose the sides of the core semiconductor chip 200C. After the filling of the pre-liner film 170 on the core semiconductor chip 200C, the upper surfaces of the uppermost second semiconductor chips 200H may be exposed by a grinding process.

In an embodiment, the pre-liner film 170 may include, for example, an epoxy-based resin, BCB, and/or polyimide, but embodiments are not limited thereto. In some embodiments, the pre-liner film 170 may include an insulating polymer material, for example, EMC, but embodiments are not limited thereto.

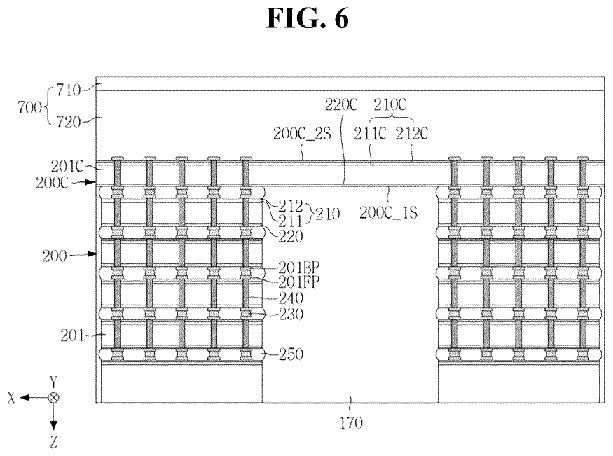

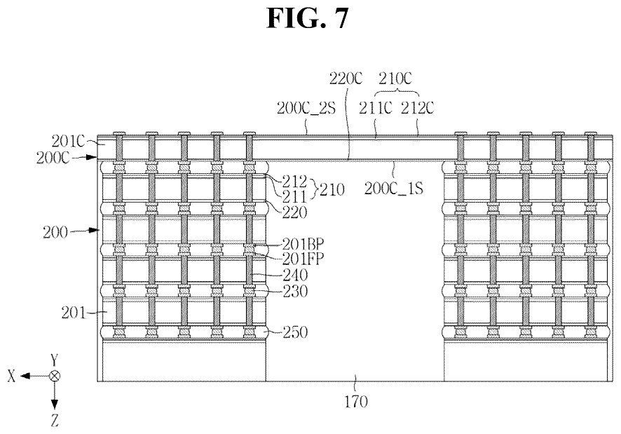

Referring to FIGS. 6 and 7, the core semiconductor chip 200C is flipped such that the second surface 200C_2S of the core semiconductor chip 200C faces upward. In other words, the core semiconductor chip 200C is flipped such that the core front structure 210C of the core semiconductor chip 200C faces upward. Thereafter, the first carrier substrate 700 is detached.

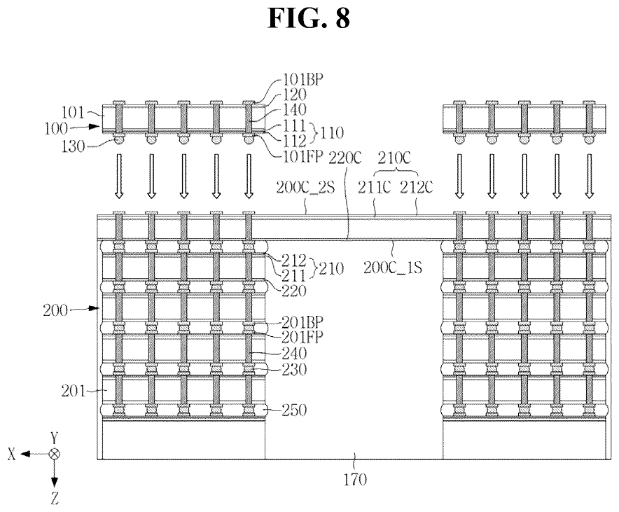

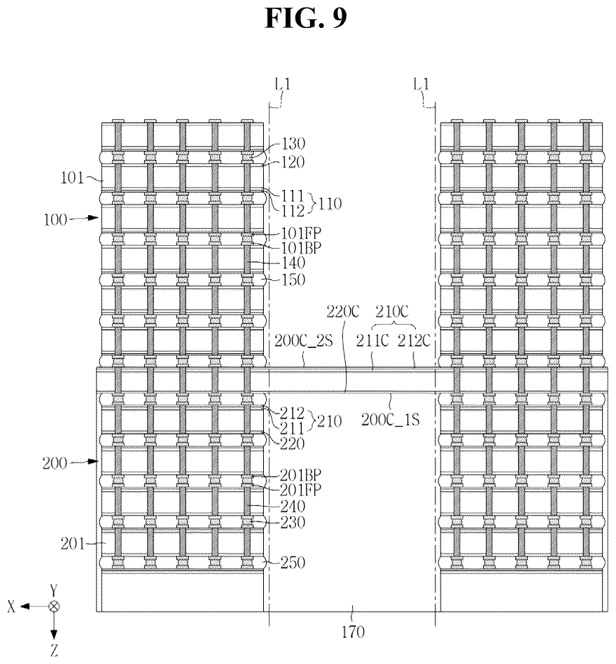

Referring to FIGS. 8 and 9, a plurality of first semiconductor chips 100 may be vertically stacked on the second surface 200C_2S of the core semiconductor chip 200C. In an embodiment, a first semiconductor chip 100 may be disposed on a left hand side of the core semiconductor chip 200C, and a first semiconductor chip 100 may be disposed on a right hand side of the core semiconductor chip 200C to be spaced apart in the first direction X from the first semiconductor chip 100 that is disposed on the left hand side, as illustrated in FIG. 8.

Each of the first semiconductor chips 100 may include the first substrate 101, the first front structure 110, the first back structure 120, the first front pads 101FP, the first back pads 101BP, the first bumps 130, and the first through vias 140.

Specifically, referring to FIG. 8, when the first semiconductor chips 100 near the core semiconductor chip 200C are disposed on the second surface 200C_2S of the core semiconductor chip 200C, the first front structures 110 of the first semiconductor chips 100 may be disposed to be oriented toward the second surface 200C_2S of the core semiconductor chip 200C. The active surfaces of the first semiconductor chips 100 may be oriented toward the core semiconductor chip 200C. The first semiconductor chips 100 may be disposed as the first bumps 130 are attached to the second front pads 201FP of the core semiconductor chip 200C.

Thereafter, referring to FIG. 9, subsequent first semiconductor chips 100 may be vertically stacked on the second surface 200C_2S of the core semiconductor chip 200C. In an embodiment, a plurality of subsequent first semiconductor chips 100 may be disposed on the left hand side of the core semiconductor chip 200C, and a plurality of subsequent first semiconductor chips 100 may be disposed on the right hand side of the core semiconductor chip 200C to be spaced apart in the first direction X from the subsequent first semiconductor chips 100 that are disposed on the left hand side, as illustrated in FIG. 9. The active surfaces of the subsequent first semiconductor chips 100 may be oriented toward the core semiconductor chip 200C. That is, the active surfaces of the subsequent first semiconductor chips 100 may be oriented toward the second surface 200C_2S of the core semiconductor chip.

A first underfill 150 may be disposed between the core semiconductor chip 200C and the first semiconductor chips 100, and between each pair of vertically adjacent first semiconductor chips 100. The first underfill 150 may surround the first bumps 130 between the core semiconductor chip 200C and the first semiconductor chips 100 and between each pair of vertically adjacent first semiconductor chips 100. The first underfill 150 may protrude beyond the sides of the first semiconductor chips 100 in the first direction X.

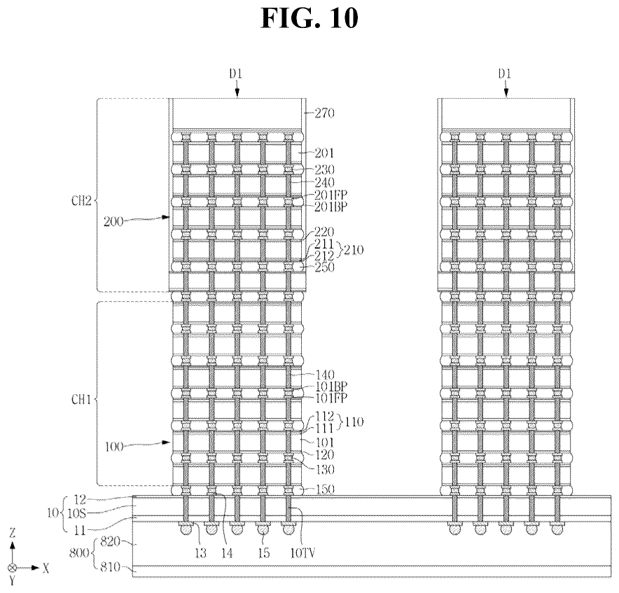

Referring to FIG. 10, through a sawing process, first dies D1, each including a first chip structure with a plurality of first semiconductor chips 100 stacked therein and a second chip structure CH2 with a plurality of second semiconductor chips 200 stacked therein, may be formed, and may be disposed on the base semiconductor chip 10.

Specifically, the core semiconductor chip 200C may be cut along first lines L1 of FIG. 9, thereby forming the first dies D1. By cutting the core semiconductor chip 200C, a liner film 270 may be formed.

Thereafter, each of the first dies D1 may be flipped such that the first and second chip structures CH1 and CH2 may be sequentially stacked on the base semiconductor chip 10. Then, the flipped first dies D1 may be disposed on the base semiconductor chip 10. The base semiconductor chip 10 may be attached onto a second carrier substrate 800, which includes a second support substrate 810 and a second glue layer 820. The description of the second carrier substrate 800 may be substantially the same as the description of the first carrier substrate 700.

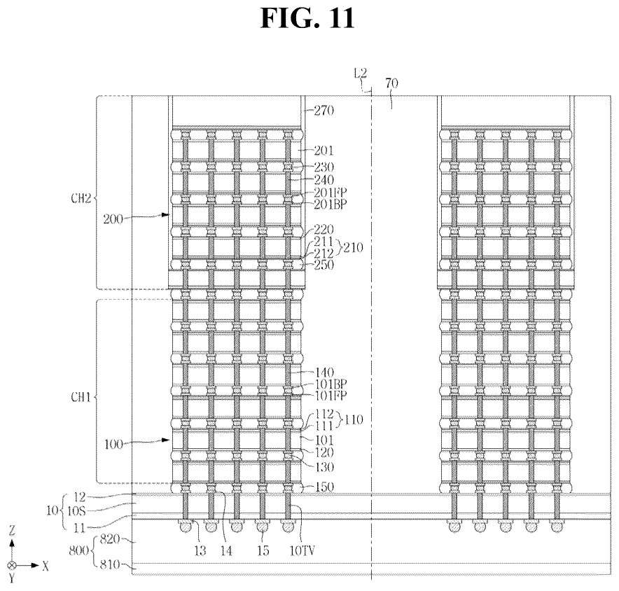

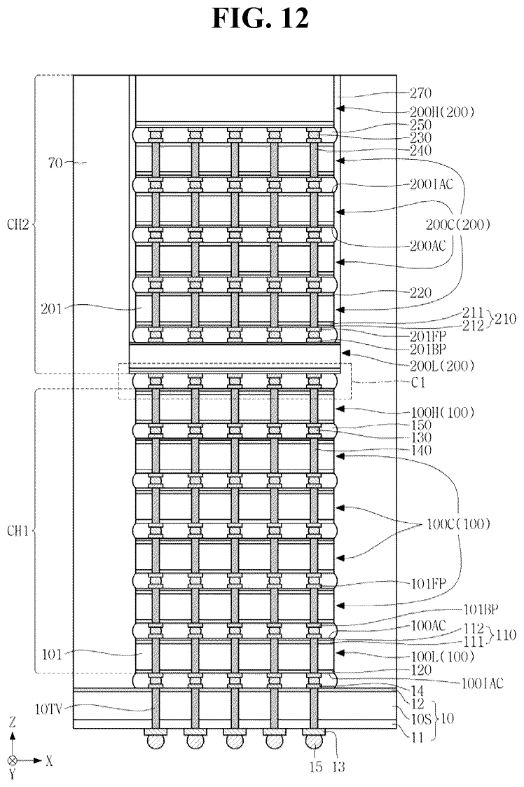

Referring to FIGS. 11 and 12, the mold layer 70 may be formed on the base semiconductor chip 10.

The mold layer 70 may be formed on the base semiconductor chip 10, covering the first chip structures CH1 and the second chip structures CH2. The mold layer 70 may cover the sides of the first semiconductor chips 100. The mold layer 70 may cover the sides of the second semiconductor chips 200. The mold layer 70 may cover the sides of the first underfill 150. The mold layer 70 may cover the sides of the second underfill 250. After the formation of the mold layer 70, the upper surfaces of the uppermost second semiconductor chips 200H may be exposed by a mold grinding process. Thereafter, by cutting along a second line L2, the final structure illustrated in FIG. 12 may be obtained.

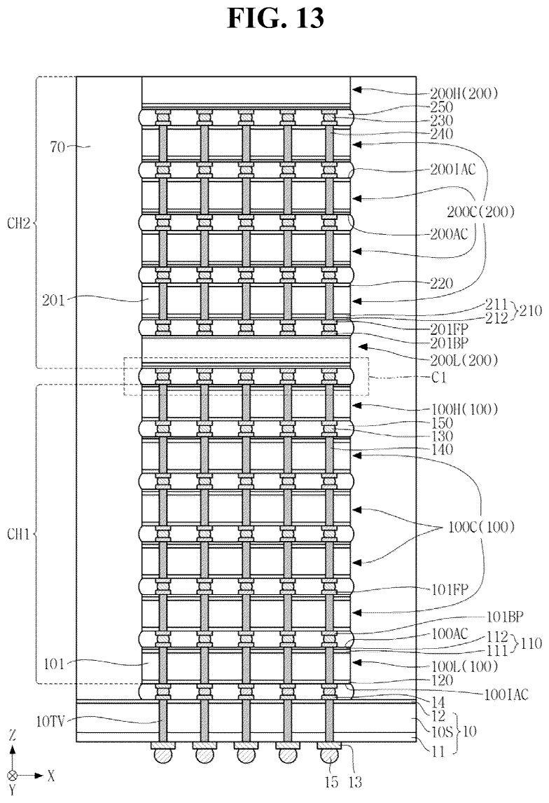

FIG. 13 is a cross-sectional view for explaining a semiconductor package according to some embodiments. For convenience, descriptions that overlap with what has been described above with reference FIGS. 1 through 12 will be simplified or omitted for conciseness.

Referring to FIG. 13, the semiconductor package according to some embodiments may include a base semiconductor chip 10, a first chip structure CH1, a second chip structure CH2, and a mold layer 70.

The first chip structure CH1 may be disposed on the upper surface of the base semiconductor chip 10. The second chip structure CH2 may be disposed on the first chip structure CH1.

The first and second chip structures CH1 and CH2 may be symmetrical with respect to a first area C1 where the first and second chip structures CH1 and CH2 are connected. The widths, in a first direction X of a plurality of first semiconductor chips 100 and a plurality of second semiconductor chips 200 may be the same. The widths, in the first direction X, of a lowermost second semiconductor chip 200L, middle second semiconductor chip 200C, an uppermost second semiconductor chip 200H, a lowermost first semiconductor chip 100L, middle first semiconductor chips 100M, and an uppermost first semiconductor chip 100H may all be the same. In other words, in the embodiment illustrated in FIG. 13, the liner film 270 may be omitted.

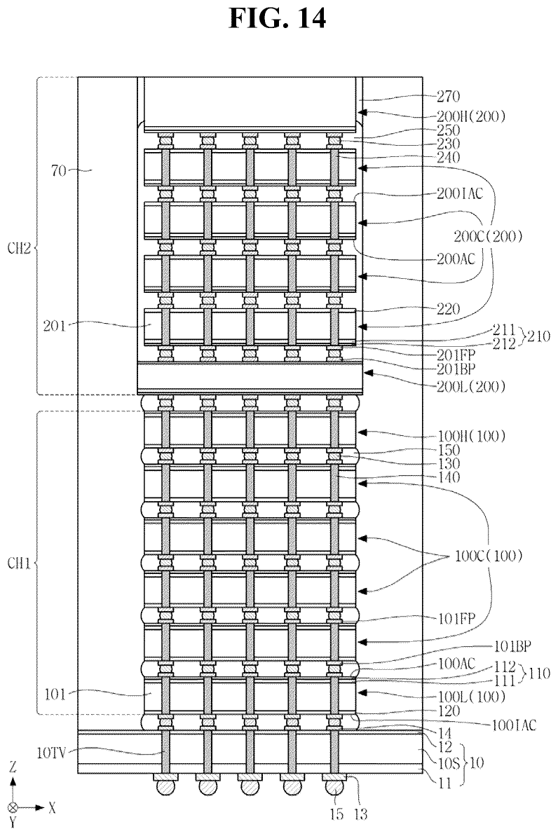

FIG. 14 is a cross-sectional view for explaining a semiconductor package according to some embodiments. For convenience, descriptions that overlap with what has been described above with FIGS. 1 through 12 will be simplified or omitted for conciseness.

Referring to FIG. 14, in a second chip structure CH2, a second underfill 250 may be disposed on a lowermost second semiconductor chip 200L. The second underfill 250 may cover the upper surface of the lowermost second semiconductor chip 200L. The second underfill 250 may also fill the space between each pair of adjacent second semiconductor chips 200.

A liner film 270 may be disposed the second underfill 250. The liner film 270 may contact the upper surface of the second underfill 250. The liner film 270 may cover parts of the sides of an uppermost second semiconductor chip 200H. In the embodiment of FIG. 14, unlike in the embodiment of FIG. 1, the liner film 270 does not contact the upper surface of the lowermost second semiconductor chip 200L.

The sides of the liner film 270, the sides of the second underfill 250, and the sides of the lowermost second semiconductor chip 200L may lie on the same planes. In other words, the sides of the liner film 270, the sides of the second underfill 250, and the sides of the lowermost second semiconductor chip 200L may be coplanar.

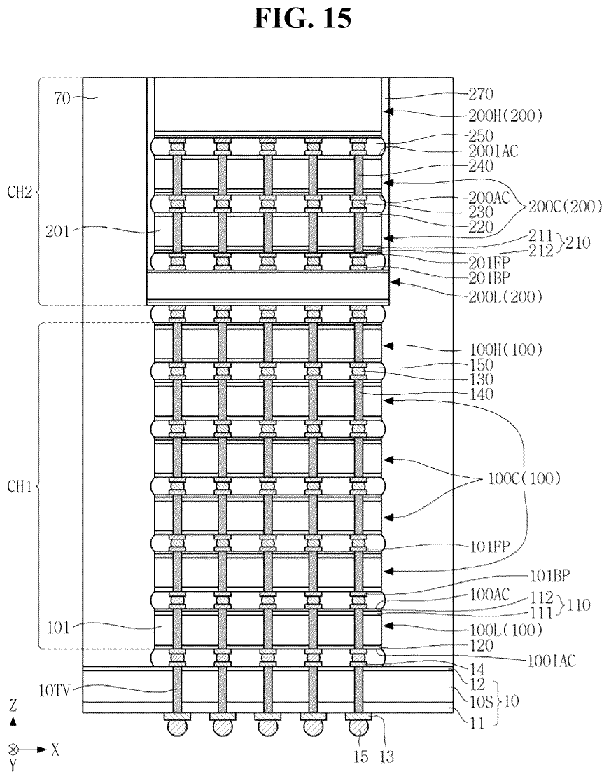

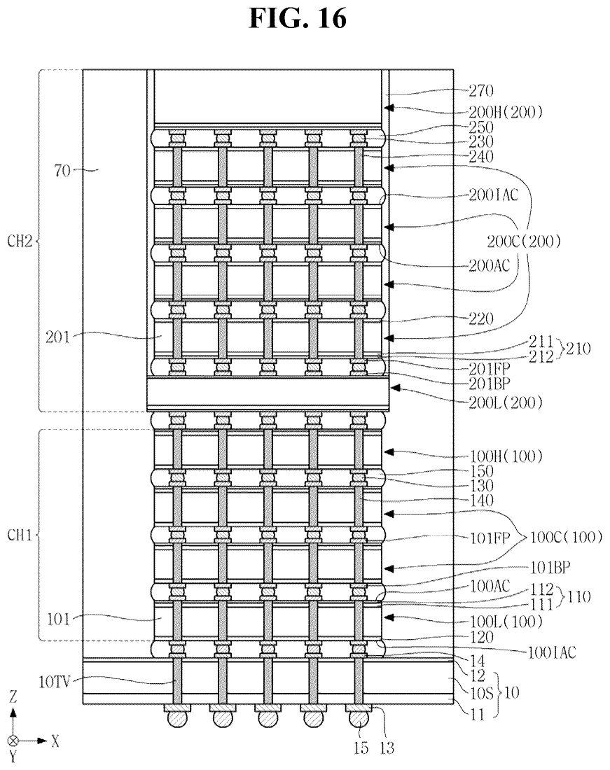

FIGS. 15 and 16 are cross-sectional views for explaining semiconductor packages according to some embodiments. For convenience, descriptions that overlap with what has been described above with FIGS. 1 through 12 will be simplified or omitted for conciseness.

Referring to FIG. 15 or 16, the semiconductor package according to some embodiments may include a first chip structure CH1 and a second chip structure CH2, which is disposed on the first chip structure CH1. The number of first semiconductor chips 100 included in the first chip structure CH1 and the number of second semiconductor chips 200 included in the second chip structure CH2 may differ. For example, as illustrated in FIG. 15, the number of second semiconductor chips 200 included in the second chip structure CH2 may be less than the number of first semiconductor chips 100 included in the first chip structure CH1. In some embodiments, as illustrated in FIG. 16, the number of second semiconductor chips 200 included in the second chip structure CH2 may be greater than the number of first semiconductor chips 100 included in the first chip structure CH1. However, embodiments are not limited thereto and, in some embodiments, the number of first semiconductor chips 100 in the first chip structure CH1 and the number of second semiconductor chips 200 in the second chip structure CH2 may be adjusted differently to that illustrated in FIGS. 15 and 16.

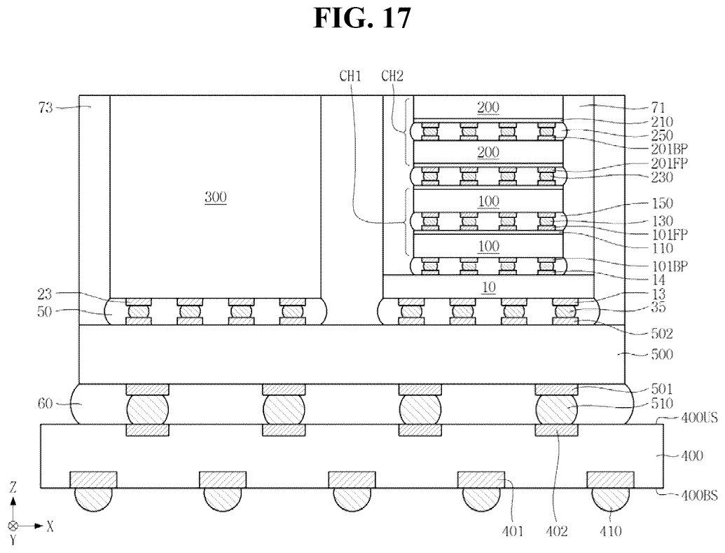

FIG. 17 is a cross-sectional view for explaining a semiconductor package according to some embodiments. For convenience, descriptions that overlap with what has been described above with FIGS. 1 through 12 will be simplified or omitted for conciseness.

Referring to FIG. 17, the semiconductor package according to some embodiments may include a circuit board 400, an interposer 500, first semiconductor chips 100, second semiconductor chips 200, and a third semiconductor chip 300.

The circuit board 400 may extend in a first direction X. In an embodiment, the circuit board 400 may be longer than the interposer 500 in the first direction X.

The circuit board 400 may be a substrate for a package. In some embodiments, the circuit board 400 may be a PCB. The circuit board 400 may have an upper surface 400US and a bottom surface 400BS, which are opposite to each other. The upper surface 400US of the circuit board 400 may face the interposer 500.

The circuit board 400 may include first board pads 401 and second board pads 402. The first board pads 401 and the second substrate pads 402 may be used to electrically connect the circuit board 400 and other components. In some embodiments, the first board pads 401 may be formed near the bottom surface 400BS of the circuit board 400, and the second board pads 402 may be formed near the upper surface 400US of the circuit board 400.

The first board pads 401 may be exposed from the bottom surface 400BS of the circuit board 400, and the second board pads 402 may be exposed from the upper surface 400US of the circuit board 400. The number and shape of the first board pads 401 and second board pads 402 may vary. In some embodiments, the first board pads 401 and the second board pads 402 may include, for example, a metal material such as Al, Cu, Ni, W, Pt, and/or Au, but embodiments are not limited thereto.

The circuit board 400 may be mounted on the mainboard of an electronic device. For example, first solder balls 410, which are connected to the first board pads 401, may be provided. The circuit board 400 may be mounted on the main board of an electronic device through the first solder balls 410. In an embodiment, the circuit board 400 may be a Ball Grid Array (BGA) board, but embodiments are not limited thereto.

In an embodiment, the first solder balls 410 may be, for example, solder bumps, but embodiments are not limited thereto. In some embodiments, the first solder balls 410 may have various shapes such as lands, balls, pins, or pillars.

The interposer 500 may facilitate the connection between the circuit board 400 and the third semiconductor chip 300. The interposer 500 may simplify the connections between the circuit board 400 and both the first semiconductor chips 100 and the second semiconductor chips 200. The interposer 500 may prevent warpage in the semiconductor package according to some embodiments. Thus, the first semiconductor chips 100, the second semiconductor chips 200, and the third semiconductor chip 300 may be electrically connected to the circuit board 400 through the interposer 500.

The interposer 500 may be disposed on the circuit board 400. In an embodiment, the interposer 500 may be a Si substrate. The interposer 500 may be, for example, a Si interposer, but embodiments are not limited thereto. In some embodiments, the interposer 500 may be formed as one of a Si substrate, an organic substrate, a plastic substrate, and/or a glass substrate.

The interposer 500 may be mounted on the upper surface 400US of the circuit board 400. For example, second solder balls 510 may be disposed between the circuit board 400 and the interposer 500. The interposer 500 may include first interposer pads 501 and second interposer pads 502. The first interposer pads 501 may be disposed on the bottom surface of the interposer 500. The second interposer pads 502 may be disposed on the upper surface of the interposer 500. The first interposer pads 501 and the second interposer pads 502 may be used to electrically connect the interposer 500 and other components.

In some embodiments, the first interposer pads 501 and the second interposer pads 502 may include, for example, a metal material such as Al, Cu, Ni, W, Pt, and/or Au, but embodiments are not limited thereto. The first interposer pads 501 and the second interposer pads 502 may have various shapes, such as circular, elliptical, or polygonal plates.

The second board pads 402 and the first interposer pads 501 may be connected by the second solder balls 510. As a result, the circuit board 400 and the interposer 500 may be electrically connected. A substrate underfill 60 may fill the space between the circuit board 400 and the interposer 500. The substrate underfill 60 may surround the second solder balls 510.

The third semiconductor chip 300 may be mounted on the interposer 500. Chip pads 23 may be disposed below the third semiconductor chip 300. The third semiconductor chip 300 may be electrically connected to the interposer 500 through the chip pads 23, connection bumps 35, and the second interposer pads 502. An interposer underfill 50 may be disposed between the interposer 500 and the third semiconductor chip 300. The interposer underfill 50 may surround the connection bumps 35, which are disposed between the interposer 500 and the third semiconductor chip 300.

The third semiconductor chip 300 may be a logic chip. For example, in some embodiments, the third semiconductor chip 300 may be an application processor (AP) such as a Field-Programmable Gate Array (FPGA), a digital signal processor, an encryption processor, a microprocessor, a microcontroller, or an Application-Specific Integrated Circuit (ASIC), but embodiments are not limited thereto.

The base semiconductor chip 10, the first semiconductor chips 100, and the second semiconductor chips 200 may be mounted on the interposer 500. In some embodiments, the base semiconductor chip 10, the first semiconductor chips 100, and the second semiconductor chips 200 may correspond to those discussed above with respect to the embodiments illustrated in FIGS. 1-16.

The base semiconductor chip 10 may be electrically connected to the interposer 500 through base front pads 13, the connection bumps 35, and the second interposer pads 502. The interposer underfill 50 may be disposed between the base semiconductor chip 10 and the interposer 500. The interposer underfill 50 may surround the connection bumps 35 between the base semiconductor chip 10 and the interposer 500.

A first chip structure CH1, which includes the first semiconductor chips 100, and a second chip structure CH2, which includes the second semiconductor chips 200, may be disposed on the base semiconductor chip 10. The second chip structure CH2 may be disposed on the first chip structure CH1. In the first chip structure CH1, the first semiconductor chips 100 may be vertically stacked. In the second chip structure CH2, the second semiconductor chips 200 may be vertically stacked.

First front structures 110 of the first semiconductor chips 100 may not be oriented toward the base semiconductor chip 10. That is, the active surfaces of the first semiconductor chips 100 may not be oriented toward the base semiconductor chip 10. The inactive surfaces of the first semiconductor chips 100 may be oriented toward the base semiconductor chip 10. Second front structures 210 of the second semiconductor chips 200 may be oriented toward the base semiconductor chip 10. That is, the active surfaces of the second semiconductor chips 200 may be oriented toward the base semiconductor chip 10.

The first semiconductor chips 100 and the second semiconductor chips 200 may be memory chips. For example, in some embodiments, the first semiconductor chips 100 and the second semiconductor chips 200 may be volatile memories such as DRAMs or SRAMs, or non-volatile memories such as flash memories, PRAMs, MRAMs, FeRAMs, or RRAMs.

The base semiconductor chip 10 and the first chip structure CH1 may be connected through base back pads 14, first bumps 130, and first back pads 101BP. The first and second chip structures CH1 and CH2 may be connected through first front pads 101FP, second bumps 230, and second front pads 201FP.

A first underfill 150 may fill the space between the base semiconductor chip 10 and the first chip structure CH1, and between each pair of adjacent first semiconductor chips 100. A second underfill 250 may fill the space between each pair of adjacent second semiconductor chips 200.

A first mold layer 71 may be disposed on the base semiconductor chip 10. The first mold layer 71 may surround the first and second chip structures CH1 and CH2. The first mold layer 71 may expose the upper surface of the uppermost second semiconductor chip 200 in the second chip structure CH2.

A second mold layer 73 may be disposed on the interposer 500. The second mold layer 73 may surround the third semiconductor chip 300, the interposer underfill 50, the base semiconductor chip 10, and the first mold layer 71. The second mold layer 73 may expose the upper surface of the third semiconductor chip 300.

Although various embodiments have been described with reference to the accompanying drawings, embodiments are not limited to the above embodiments and may be implemented in various different forms. Those of ordinary skill in the technical field to which the present disclosure belongs will be able to understand that the present disclosure may be implemented in other specific forms without changing the technical idea or essential characteristics of the present disclosure. Therefore, it should be understood that the embodiments as described above are not restrictive but illustrative in all respects.

What is claimed is:

1. A semiconductor package comprising:
a base semiconductor chip;
a first chip structure including a plurality of first semiconductor chips that are vertically stacked on the base semiconductor chip; and
a second chip structure disposed on the first chip structure and including a plurality of second semiconductor chips that are vertically stacked on the first chip structure,
wherein:
inactive surfaces of the plurality of first semiconductor chips are oriented in a first direction with respect to the base semiconductor chip, and
active surfaces of the plurality of second semiconductor chips are oriented in the first direction with respect to the base semiconductor chip.

2. The semiconductor package of claim 1, wherein:
a first underfill disposed between each pair of adjacent first semiconductor chips, in the first chip structure;
a second underfill disposed between each pair of adjacent second semiconductor chips, in the second chip structure;
a mold layer surrounding the first chip structure and the second chip structure; and
a liner film disposed between the second underfill and the mold layer,
wherein, in the first chip structure, the first underfill directly contacts the mold layer.

3. The semiconductor package of claim 2, wherein:
the plurality of second semiconductor chips include a lowermost second semiconductor chip, an uppermost second semiconductor chip, and one or more middle second semiconductor chips disposed between the lowermost second semiconductor chip and the uppermost second semiconductor chip, and
the liner film exposes sides of the lowermost second semiconductor chip and sides of the one or more middle second semiconductor chips.

4. The semiconductor package of claim 3, wherein the liner film contacts an upper surface of the lowermost second semiconductor chip.

5. The semiconductor package of claim 3, wherein an upper surface of the uppermost second semiconductor chip is not covered by the liner film.

6. The semiconductor package of claim 1, wherein:
the plurality of second semiconductor chips include a lowermost second semiconductor chip, an uppermost second semiconductor chip, and one or more middle second semiconductor chips disposed between the lowermost second semiconductor chip and the uppermost second semiconductor chip, and
a width, in a horizontal direction that is parallel to an upper surface of the base semiconductor chip, of the lowermost second semiconductor chip is greater than widths, in the horizontal direction, of the one or more middle second semiconductor chips and the uppermost second semiconductor chip.

7. The semiconductor package of claim 6, wherein widths, in the horizontal direction, of the plurality of first semiconductor chips within the first chip structure are the same.

8. The semiconductor package of claim 1, wherein a first thickness, in a vertical direction that is perpendicular to an upper surface of the base semiconductor chip, of an uppermost second semiconductor chip among the plurality of second semiconductor chips is greater than a second thickness, in the vertical direction, of the plurality of first semiconductor chips and a third thickness, in the vertical direction, of the plurality of second semiconductor chips other than the uppermost second semiconductor chip.

9. The semiconductor package of claim 1, wherein:
the plurality of first semiconductor chips include first active surfaces and first inactive surfaces,
the plurality of second semiconductor chips include second active surfaces and second inactive surfaces, and
with respect to an upper surface of the base semiconductor chip, the first inactive surfaces are higher than the first inactive surfaces and the second active surfaces are lower than the second inactive surfaces.

10. The semiconductor package of claim 1, wherein the first chip structure and the second chip structure are symmetrical with respect to a first area in which the first chip structure and the second chip structure are connected.

11. The semiconductor package of claim 1, wherein first active surfaces of the plurality of first semiconductor chips of the first chip structure face second inactive surfaces of the plurality of second semiconductor chips of the second chip structure.

12. A semiconductor package comprising:
a base semiconductor chip;
a first chip structure including a plurality of first semiconductor chips that are vertically stacked on an upper surface of the base semiconductor chip; and
a second chip structure disposed on the first chip structure and including a plurality of second semiconductor chips that are vertically stacked on the first chip structure,
wherein:
the plurality of first semiconductor chips include first front structures with first active surfaces and first back structures with first inactive surfaces,
the plurality of second semiconductor chips include second front structures with second active surfaces and second back structures with second inactive surfaces,
the first inactive surfaces are oriented in a first direction with respect to the base semiconductor chip, and
the second inactive surfaces are oriented in the first direction with respect to the base semiconductor chip.

13. The semiconductor package of claim 12, wherein, with respect to the upper surface of the base semiconductor chip, the first front structures are higher than the first back structures and the second front structures are lower than the second back structures.

14. The semiconductor package of claim 12, further comprising:
a first underfill disposed between each pair of adjacent ones of the plurality of first semiconductor chips in the first chip structure;
a second underfill disposed between each pair of adjacent ones of the plurality of second semiconductor chips in the second chip structure; and
a mold layer surrounding the first chip structure and the second chip structure,
wherein, with respect to the upper surface of the base semiconductor chip, an uppermost second semiconductor chip among the plurality of second semiconductor chips is on a same level as an upper surface of the mold layer.

15. The semiconductor package of claim 14, wherein a thickness, in a vertical direction that is perpendicular to the upper surface of the base semiconductor chip, of the uppermost second semiconductor chip is greater than a second thickness, in the vertical direction, of the plurality of first semiconductor chips and a third thickness, in the vertical direction, of the plurality of second semiconductor chips other than the uppermost second semiconductor chip.

16. The semiconductor package of claim 14, further comprising:
a liner film disposed between the second underfill and the mold layer.

17. The semiconductor package of claim 12, wherein:
the plurality of second semiconductor chips include a lowermost second semiconductor chip, an uppermost second semiconductor chip, and one or more middle second semiconductor chips disposed between the lowermost second semiconductor chip and the uppermost second semiconductor chip, and
a width, in a horizontal direction that is parallel to the upper surface of the base semiconductor chip, of the lowermost second semiconductor chip is greater than widths, in the horizontal direction, of the one or more middle second semiconductor chips and the uppermost second semiconductor chip.

18. A method of fabricating a semiconductor package, the method comprising:
providing a core semiconductor chip, which is disposed on a carrier substrate and includes a first surface, and a second surface that is opposite to the first surface and that is bonded to the carrier substrate;
forming a second chip structure, which includes a plurality of second semiconductor chips that are vertically stacked to have active surfaces of the plurality of second semiconductor chips oriented toward the core semiconductor chip, on the first surface, the core semiconductor chip forming a lowermost second semiconductor chip;
flipping the carrier substrate such that the second surface is above the first surface, and detaching the carrier substrate;
forming a first chip structure, which includes a plurality of first semiconductor chips that are vertically stacked to have active surfaces of the plurality of first semiconductor chips oriented toward the second surface, on the second surface of the core semiconductor chip, to form a first die including the first chip structure and the second chip structure; and
flipping the first die such that the first chip structure and the second chip structure are sequentially stacked, and attaching the first die that has been flipped on a base semiconductor chip.

19. The method of claim 18, further comprising:
forming a second underfill between each pair of adjacent ones of the plurality of second semiconductor chips;
forming a first underfill between the base semiconductor chip and the first chip structure, and between each pair of adjacent ones of the plurality of first semiconductor chips; and
forming a mold layer that surrounds the first chip structure and the second chip structure, on the base semiconductor chip.

20. The method of claim 18, wherein the active surfaces of the plurality of second semiconductor chips are oriented toward an upper surface of the base semiconductor chip.
